(19) United States
(12) Patent Application Publication
(10) Pub. No.: US 2007/0089012 A1
(43) Pub. Date: Apr. 19, 2007

(54) SYSTEM AND METHOD FOR TESTING A LIGHT EMITTING DIODE PANEL

(76) Inventors: Wei-Yuan Chen, Shenzhen (CN); Chao-Tsung Fan, Shenzhen (CN); Po-Chang Wang, Shenzhen (CN); Li-Ying Chang, Shenzhen (CN)

Correspondence Address: NORTH AMERICA INTELLECTUAL PROPERTY CORPORATION, P.O. BOX 506, MERRIFIELD, VA, 22116, US

(21) Appl. No.: 11/309,181

(22) Filed: Jul. 7, 2006

(30) Foreign Application Priority Data
Jul. 27, 2005 (CN) 200510036252.0

(51) Int. Cl. G01R 31/28; G06F 11/00

(52) U.S. Cl. 714/742

(57) ABSTRACT

An exemplary system for testing light emitting diode (LED) panel is disclosed. The system includes: a symbol arranging module (12) for arranging a group of symbols; an input/output module (14) for outputting a symbol and corresponding number of lightening LEDs displayed on the LED panel, and receiving a symbol and the number of corresponding lightening LED input by a test engineer; a comparing module (16) for comparing the output data with the received data and computing a test result; a test result displaying module (18) for displaying the test result. A related method is also disclosed.

### FIELD OF THE INVENTION

The present invention relates to systems and methods for testing a panel, and more particularly to a system and method for testing a light emitting diode panel.

### DESCRIPTION OF RELATED ART

Light emitting diode (LED) display apparatuses using LED panels are employed for displaying. An LED panel is constructed to include a plurality of LEDs arranged in columns and rows to form a so-called dot matrix that is configured to display characters, figures, and so on by activating a predetermined combination of LEDs on the LED panel using a dynamic drive circuit composed of transistors.

Traditionally, the LED panel is tested by powering it on and off. When the LED panel is powered on, all the LEDs on the LED panel are lightened; contrary, all the LEDs on the LED panel are dark when powered off. The method of testing an LED panel is prone to result errors. For example, if a single LED on the LED panel is not lightened when the LED panel is powered on, an operator may overlook it and consider all the LEDs are lightened through carelessness, resulting in an incorrect test result.

What is needed, therefore, is a method for testing an LED panel correctly.

### SUMMARY OF INVENTION

A system for testing a light emitting diode (LED) panel is provided. The LED panel includes a plurality of LEDs thereon. The system includes a symbol arranging module, an input/output module, a comparing module and a test result displaying module. The symbol arranging module is configured for arranging output data, the output data include a group of symbols and numerical values that represent the number of LEDs required to be lightened for each symbol, all the symbols collectively cover all the LEDs on the LED panel. The input/output module is configured for displaying each symbol of the group by lightening corresponding LEDs on the LED panel, and receiving test data on each symbol, the test data include the symbol and a corresponding number of lightening LEDs. The comparing module is configured for comparing the output data with the received test data on each symbol, and computing a test result according to the comparison. The test result displaying module is configured for displaying the test result on a monitor.

A method for testing the LED panel is provided. The method includes the steps of: arranging an output data, the output data comprising a group of symbols and numeric values that represents the number of LEDs required to be lightened for each symbol, all the symbols of the group collectively covers all LEDs on the LED panel; displaying each symbol of the group by lightening corresponding LEDs on the LED panel; receiving test data on each symbol manually, the test data comprising the symbol and corresponding number of lightened LEDs; comparing the output data with the received test data on each symbol, and computing a test result; and displaying the test result.

Other systems, methods, features, and advantages of the present invention will be or become apparent to one with skill in the art upon examination of the following drawings and detailed description.

### BRIEF DESCRIPTION OF DRAWINGS

FIG. 1 is a schematic diagram of hardware configuration of a system for testing a light emitting diode (LED) panel in accordance with one embodiment;

FIG. 2 is a schematic diagram of software function modules of a testing device in FIG. 1;

FIG. 3 is a schematic diagram illustrating a group of statuses of lightening LEDs on the LED panel of FIG. 1; and

FIG. 4 is a flowchart of a preferred method for testing an LED panel in accordance with one embodiment.

### DETAILED DESCRIPTION

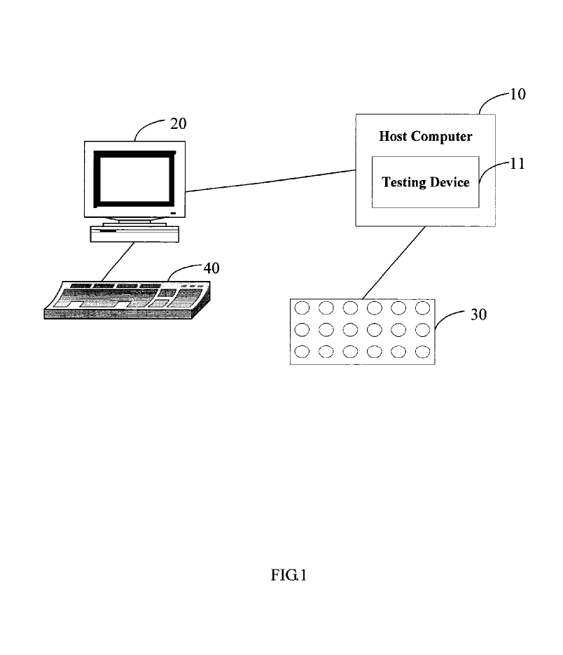

FIG. 1 is a schematic diagram of hardware configuration of a system for testing a light emitting diode (LED) panel (hereinafter, “the system”) in accordance with one preferred embodiment. The system typically includes a host computer 10, a monitor 20, an LED panel 30, and a keyboard 40. The host computer 10 can be an IBM clone personal computer (PC) installed with a testing device 11 therein. The testing device 11 is configured for testing LED panels, such as the LED panel 30. The monitor 20 is configured for providing an interface for displaying related data and test results. The keyboard 40 is configured for inputting data.

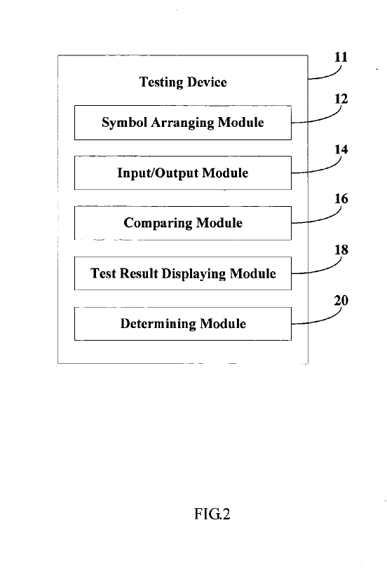

FIG. 2 is a schematic diagram of software function modules of the testing device 11 in FIG. 1. The testing device 11 mainly includes a symbol arranging module 12, an input/output module 14, a comparing module 16, a test result displaying module 18, and a determining module 20.

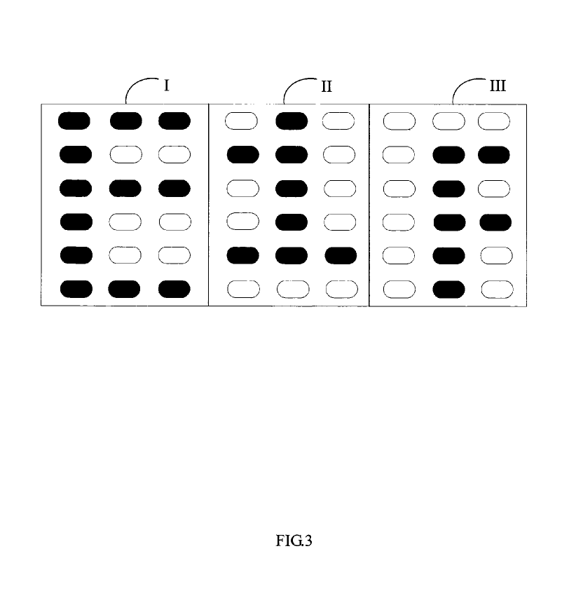

The symbol arranging module 12 is configured for arranging at least one group of symbols. Each symbol further has a corresponding numeric value that represents a number of lightened LEDs required to display the symbol. Such symbol can be an English letter, a figure, or an arrowhead. All the symbols of the group of symbols collectively cover all LEDs of the LED panel 30, that is, each LED on the LED panel 30 is lightened at least once (illustrated in FIG. 3) after all the symbols of the group of symbols have been displayed. For example, when the LED panel 30 is a 6 by 3 array, the group of symbols can be “E, 1, F,” or “C, 7, E,” or “5, C, 2” and so on.

The input/output module 14 is configured for outputting data, the output data include each symbol of the group of symbols that has not been displayed on the LED panel 30, and displaying the symbol on the LED panel 30. The input/output module 14 is further configured for receiving test data on each displayed symbol inputted by a test engineer, the test data include the symbol and a corresponding number of lightened LEDs. The comparing module 16 is configured for comparing the output data with the test data on each symbol of the group of symbols, and for computing a test result according to the comparison. The test result displaying module 18 is configured for displaying the test result of the LED panel 30 on a monitor. The determining module 20 is configured for determining whether all the symbols of the group of symbols have been displayed on the LED panel 30.

FIG. 3 is a schematic diagram illustrating a group of lightened LEDs statuses on the LED panel 30. There are three parts: part I, part II, and part III, which collectively form a group of lightened LEDs statuses. Part I displays an English letter “E,” and the number of lightened LEDs covered by the English letter “E” is twelve. Part II displays a figure “1”, and the number of lightened LEDs covered by the figure “1” is eight. Part III displays an English letter “F,” and the number of lightened LEDs covered by the English letter “F” is seven. All the LEDs in the group of lightened LEDs statuses are lightened at least one time.

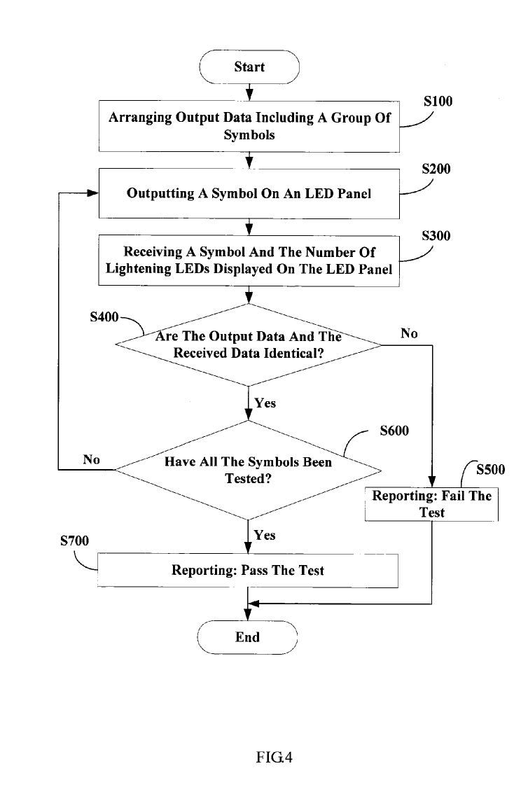

FIG. 4 is a flowchart of a preferred method for testing the LED panel 30 in accordance with one embodiment. In step S100, the symbol arranging module 12 arranges a group of symbols and corresponding symbol's numeric value that represents the number of LEDs required to be lightened for each symbol. The group of symbols is required to ensure that each LED on the LED panel 30 must be lightened at least once after all the symbols have been displayed.

In step S200, the input/output module 14 outputs data to the monitor 20, the output data includes a symbol of the group of symbols that has not been displayed on the LED panel 30, and the LED panel 30 displays the symbol. Each symbol requires a corresponding number of lightened LEDs.

In step S300, the input/output module 14 receives the test data. The received test data are inputted by the test engineer by utilizing the keyboard 40, and include the symbol and the corresponding number of lightened LEDs that are displayed on the LED panel 30.

In step S400, the comparing module 16 compares the output data with received test data and computes a test result according to the comparison. The test result displaying module 18 displays the test result. In step S500, the test result displaying module 18 reports that the LED panel 30 fails the test if the output data and the received test data are different; LEDs of the LED panel have some error.

In step S600, the determining module 20 determines whether all the symbols of the group of symbols have been displayed on the LED panel 30 if the output data and the received test data are identical. In step S700, the test result displaying module 18 reports that the LED panel 30 passes the test if all the symbols of the group of symbols have been tested and all the output data and the received test data are identical.

It is to be understood that, in step S300, when the symbol is an English letter, there is no significant if the test data inputted by the test engineer is an uppercase or a lower case.

In step S600, the procedure returns the step S200 if any symbol of the group of symbols has not been displayed on the LED panel 30.

Although the present invention has been specifically described on the basis of a preferred embodiment and preferred method, the invention is not to be construed as being limited thereto. Various changes or modifications may be made to the embodiment and method without departing from the scope and spirit of the invention.

What is claimed is:

1. A system for testing a light emitting diode (LED) panel, the LED panel comprising a plurality of LEDs thereon, the system comprising:
a symbol arranging module for arranging output data, the output data comprising a group of symbols and numerical values that represent the number of LEDs required to be lightened for each symbol, all the symbols collectively cover all the LEDs on the LED panel;
an input/output module for displaying each symbol of the group of symbols by lightening corresponding LEDs on the LED panel, and receiving test data on each symbol, the test data comprising the symbol and a corresponding number of lightening LEDs;
a comparing module for comparing the output data with the received test data on each symbol, and computing a test result according to the comparison; and
a test result displaying module for displaying the test result on a monitor.

2. The system as claimed in claim 1, further comprising a determining module for determining whether all the symbols of the group of symbols have been tested if the output data and the received test data are identical.

3. The system as claimed in claim 1, wherein the test result denotes that the LED panel fails in the test if the output data and the received test data are different.

4. A method for testing a light emitting diode (LED) panel, the LED panel comprising a plurality of LEDs thereon, the method comprising the steps of:
arranging an output data, the output data comprising a group of symbols and numeric values that represents the number of LEDs required to be lightened for each symbol, all the symbols of the group of symbols collectively covers all LEDs on the LED panel;
displaying each symbol of the group of symbols by lightening corresponding LEDs on the LED panel;
receiving test data on each symbol input manually, the test data comprising the symbol and corresponding number of lightened LEDs;
comparing the output data with the received test data on each symbol, and computing a test result; and
displaying the test result.

5. The method according to claim 4, further comprising the steps of:
determining whether all the symbols of the group of symbols have been tested if the output data and the received data are identical;
reporting a test result denoting that the LED panel passes the test if all the symbols of the group of symbols have been tested and all the output data and the received test data are identical.

6. The method according to claim 5, wherein the test result denotes that the LED panel fails in the test if the output data and the received test data are different.
